(19) United States
(12) Patent Application Publication
(10) Pub. No.: US 2026/0226989 A1
(43) Pub. Date: Aug. 6, 2026

(54) REACTOR GATE VALVE

(71) Applicant: Helios Technical Services, LLC, Cave Creek, AZ (US)

(72) Inventors: Steven Burch, Cave Creek, AZ (US); Mike Halpin, Scottsdale, AZ (US)

(21) Appl. No.: 18/872,141

(22) PCT Filed: Jun. 7, 2023
(86) PCT No.: PCT/US2023/024751

§ 371 Date: Dec. 5, 2024

Related U.S. Application Data
(60) Provisional application No. 63/349,915, filed on Jun. 7, 2022.

(51) Int. Cl. F16K 3/18; F16K 3/02; H10P 72/00

(52) U.S. Cl. CPC F16K 3/182; F16K 3/0254; H10P 72/0402

(57) ABSTRACT

In some aspects, the techniques described herein relate to a gate valve configured to engage an outer surface of a wall of a reaction chamber to form a seal about an opening in the wall of the reaction chamber, including a plate including a groove; a seal element disposed within the groove; and a hinge mechanism coupled to the plate and to the reaction chamber, the hinge mechanism being configured to translate between a closed position in which the plate and the seal element are pressed gain the wall of the reaction chamber in a direction that is perpendicular to the outer surface of the wall and an open position in which the plate and the seal element are not in direct contact with the reaction chamber.

### CROSS-REFERENCE TO RELATED APPLICATIONS

This application claims priority to U.S. Provisional Patent Application No. 63/349,915 entitled “REACTOR GATE VALVE” and filed on Jun. 7, 2022, which is hereby incorporated by reference.

### TECHNICAL FIELD

The present invention generally relates to closure systems for semiconductor fabrication tools and devices and, specifically, to a gate valve for a semiconductor reactor tool.

### BACKGROUND OF THE INVENTION

Semiconductor devices are commonly found in modern electronic products. Semiconductor devices vary in the number and density of electrical components. Discrete semiconductor devices generally contain one type of electrical component, e.g., light emitting diode (LED), small signal transistor, resistor, capacitor, inductor, and power metal oxide semiconductor field effect transistor (MOSFET). Integrated semiconductor devices typically contain hundreds to millions of electrical components. Examples of integrated semiconductor devices include microcontrollers, microprocessors, charged-coupled devices (CCDs), solar cells, and digital micro-mirror devices (DMDs).

Semiconductor devices perform a wide range of functions such as signal processing, high-speed calculations, transmitting and receiving electromagnetic signals, controlling electronic devices, transforming sunlight to electricity, and creating visual projections for television displays. Semiconductor devices are found in the fields of entertainment, communications, power conversion, networks, computers, and consumer products. Semiconductor devices are also found in military applications, aviation, automotive, industrial controllers, and office equipment.

Semiconductor devices exploit the electrical properties of semiconductor materials. The atomic structure of semiconductor material allows its electrical conductivity to be manipulated by the application of an electric field or base current or through the process of doping. Doping introduces impurities into the semiconductor material to manipulate and control the conductivity of the semiconductor device.

A semiconductor device contains active and passive electrical structures. Active structures, including bipolar and field effect transistors, control the flow of electrical current. By varying levels of doping and application of an electric field or base current, the transistor either promotes or restricts the flow of electrical current. Passive structures, including resistors, capacitors, and inductors, create a relationship between voltage and current necessary to perform a variety of electrical functions. The passive and active structures are electrically connected to form circuits, which enable the semiconductor device to perform high-speed calculations and other useful functions.

Semiconductor devices are generally manufactured using two complex manufacturing processes, i.e., front-end manufacturing, and back-end manufacturing, each involving potentially hundreds of steps. Front-end manufacturing involves the formation of a plurality of die on the surface of a semiconductor wafer. Each die is typically identical and contains circuits formed by electrically connecting active and passive components. Back-end manufacturing involves singulating individual die from the finished wafer and packaging the die to provide structural support and environmental isolation.

Wafer processing techniques often involve high temperatures and the deposition of material via exposure of the wafer substrate to gases having carefully controlled compositions. This requires a controlled environment and so these manufacturing steps are often performed within a reaction chamber. The chamber should be sealed during wafer processing and allows precise control over temperature and gas or vapor content within the chamber.

In a typical reaction chamber, the opening through which the wafer is introduced into and later removed from the interior volume chamber is covered by a gate that should form a seal around the opening. These conventional reaction chamber gates suffer from several problems.

Some conventional reaction chamber gates open by rotating away from the reaction chamber opening. Because they only rotate away from the opening, such gates, even when open, are at least partially positioned in front of the reaction chamber opening. In this position, the gate (and specifically, the gate's delicate seal) is directly exposed to infrared radiation emitted from the interior of the reaction chamber. This radiation strikes the gate's seal and can rapidly degrade the material of the seals, thereby degraded the quality of seal formed by the gate when it is closed against the reaction chamber's opening. Additionally, the act of closing such a gate structure can itself cause physical damage to the gate's seal as the rotational closing mechanism can result in a portion of the gate's seal being dragged along a portion of the outer surface of the reaction chamber, resulting in rolling of and damage to the seal.

Other types of reaction chamber gates can operate via rotation in combination with some seal-forming linear motion. But such gate designs suffer deficiencies in which poor sealing and particle creation problems can occur. Additionally, such gates continue to expose the sealing surface of the gate to lamp radiation degrading the O-ring seal of such gates.

Because conventional reaction chamber gates open and close via a rotational mechanism, the act of closing such a gate can cause physical damage to the gate's seal as the rotation closing mechanism can result in a portion of the gate's seal being dragged along a portion of the outer surface of the reaction chamber, resulting in rolling of and damage to the seal.

Conventional reaction chamber gates are also very difficult to service as the gate seal must be replaced in situ. Because the reaction gates only open a small distance, the seal replacement process is difficult to implement and can result in significant downtime of the reaction chamber resulting in substantial lost production.

In some circumstances it may be necessary to remove the entire gate structure from the reaction chamber in order to properly service the gate's seal. In that case, when reinstalling the gate structure into the reaction chamber, a complicated and lengthy process must be followed to ensure that the replaced gate structure is properly aligned against the reaction chamber.

### BRIEF DESCRIPTION OF THE FIGURES

A more complete understanding of the subject matter may be derived by referring to the detailed description and claims when considered in conjunction with the following figures, wherein like reference numbers refer to similar elements throughout the figures.

FIGS. 1A and 1B depict front perspective and rear perspective views, respectively, of gate valve system 100.

FIG. 2A depicts two different plates 112 depicting a groove 114 for receipt of a suitable seal as well as holes 113 configured to receive distance measuring screws 120 (described below).

FIG. 2B is a detail view depicting a portion of bracket 111 of gate valve system 100.

FIG. 3 is a photograph depicting an example installed of gate valve system 100 in a wafer handling chamber and in conjunction with a reaction chamber.

FIGS. 4A-4C depict side views of gate valve system 100 while gate valve system 100 is transitioning from a fully closed position to a fully open position.

FIGS. 5A-5C depict side views of gate valve system 100 while gate valve system 100 is transitioning from an open position to a closed position.

### DETAILED DESCRIPTION

The following description recites various aspects and embodiments of the invention disclosed herein. No particular embodiment is intended to define the scope of the invention. Rather, the embodiments provide non-limiting examples of various configurations, and methods that are included within the scope of the claimed invention. The description is to be read from the perspective of one of ordinary skill in the art. Therefore, information that is well known to the ordinarily skilled artisan is not necessarily included.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits.

Components are formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices, transforming the semiconductor material into an insulator, conductor, or dynamically changing the semiconductor material conductivity in response to an electric field or base current. Transistors contain regions of varying types and degrees of doping arranged as necessary to enable the transistor to promote or restrict the flow of electrical current upon the application of the electric field or base current.

Active and passive components are formed by layers of materials with different electrical properties. The layers can be formed by a variety of deposition techniques determined in part by the type of material being deposited. For example, thin film deposition may involve chemical vapor deposition (CVD), physical vapor deposition (PVD), electrolytic plating, and electroless plating processes. Each layer is generally patterned to form portions of active components, passive components, or electrical connections between components.

The layers can be patterned using photolithography, which involves the deposition of light sensitive material, e.g., photoresist, over the layer to be patterned. A pattern is transferred from a photomask to the photoresist using light. The portion of the photoresist pattern subjected to light is removed using a solvent, exposing portions of the underlying layer to be patterned. The remainder of the photoresist is removed, leaving behind a patterned layer. Alternatively, some types of materials are patterned by directly depositing the material into the areas or voids formed by a previous deposition/etch process using techniques such as electroless and electrolytic plating.

Depositing a thin film of material over an existing pattern can exaggerate the underlying pattern and create a non-uniformly flat surface. A uniformly flat surface is required to produce smaller and more densely packed active and passive components. Planarization can be used to remove material from the surface of the wafer and produce a uniformly flat surface. Planarization involves polishing the surface of the wafer with a polishing pad. An abrasive material and corrosive chemical are added to the surface of the wafer during polishing. The combined mechanical action of the abrasive and corrosive action of the chemical removes any irregular topography, resulting in a uniformly flat surface.

These fabrication processes may involve the processing of the wafer substrate at precisely controlled temperatures and in specific gaseous environment. To enable precise control over such fabrication steps, wafer processing often occurs within a sealed reaction chamber that enables precise control of the ambient temperature, gas content, and pressure.

The present disclosure provides an improved reaction chamber gate valve system configured to close and seal the opening of a reaction chamber through which wafers are introduced into the interior volume of the reaction chamber or removed therefrom. The seal is therefore configured to retain the toxic and caustic gases associated with wafer processing within the reaction chamber during various wafer processing steps.

The present reaction chamber gate valve includes a drop-in replaceable gate plate structure allowing efficient and simplified replacement of gate valve seals. As described herein, the gate structure can be removed from the gate valve hinge mechanism allowing easier and quicker replacement of the seal element. Additionally, due in part to how the replaceable gate structure installs into the gave valve housing, there is no (or significantly reduced) need to realign the gate valve structure after the seal element is replaced.

When moving between closed and open positions, the hinge mechanism of the present gate valve structure is configured so that in its open position, the gate structure is moved into position away and displaced from the reaction chamber opening. As such, when the gate valve is in its fully open position, the seal element of the gate valve is not in line-of-sight to the interior of the reaction chamber and is therefore not directly exposed to light energy (or other radiation) emanating from the interior of the reaction chamber. This protects the seal element and can extend its operational lifetime over conventional designs.

Furthermore, when the present gate valve is transitioned into a closed position, the hinge design provides that the gate structure is pressed linearly against the reaction chamber housing (and, specifically, pressed against the reaction chamber opening flange in a direction orthogonal to or perpendicular to the surface of the flange) to seal the reaction chamber opening. In other words, the hinge design provides that the gate plate structure is traveling orthogonally to the outer surface of the flange of the reaction chamber as the gate valve is closed. This linear orthogonal motion provides that the seal element of the present gate valve is pressed against the reaction chamber with no sideways motion and so the does not experience rolling or dragging of the valve plate (and the seal element) as the gate valve is closed. Instead, the valve plate (and seal embedded therein) of the present gate valve is pressed directly upon the surface of the reaction chamber opening when the gate valve is closed. This can prevent “rolling” of the seal element, as described herein, which can damage the seal element.

The present gate valve structure may be implemented as a drop-in replacement for OEM-style gate valves on certain model tool systems. The present gate valve structure may be further implemented using conventional OEM plumbing and pneumatic and electrical connections to facilitate installation in existing reaction chamber systems.

The present gate valve structure is therefore more easily serviceable than conventional designs. Furthermore, as described herein and illustrated in the figures, the present gave valve design may incorporate additional features to facilitate initial installation and alignment of the gate valve structure in a particular reaction chamber. Then, the removable gate valve structure can be easily removed for maintenance (e.g., via replacement of the gate structure's sealing element). When the removable gate structure is replaced, it is self-aligning to allow rapid and reliable maintenance. This may be in contrast to conventional reaction chamber gate structures, which typically require realignment of the entire gate structure whenever maintenance is performed.

Additionally, because the gate of the present gate valve system is removable, leak check and seal state analysis can be performed away from the reaction chamber. While that analysis is ongoing, a second replaceable gate can easily be installed into the present gate valve system to allow ongoing use of the reaction chamber even while the first removable gate is analyzed, serviced, or replaced.

The present gate valve system and, specifically, the hinge design allows the present gate valve system to meet seal element compression requirements that are not met by many conventional OEM systems. Specifically, the present gate valve structure can satisfy standard 20% seal or O-ring compression standard requirements, which, in testing, exhibits improvement over conventional designs. Specifically, the present gate valve linkage, as described herein, enables an appropriate normal force to be applied to the gate valve's seal by an appropriately-sized gate valve pneumatic actuator cylinder.

Referring now to the drawings, like reference numerals are used to identify identical components in the various views.

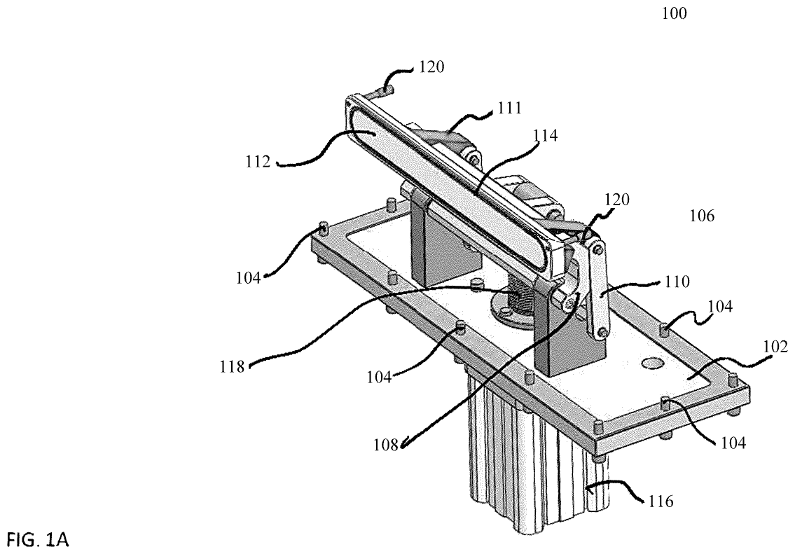

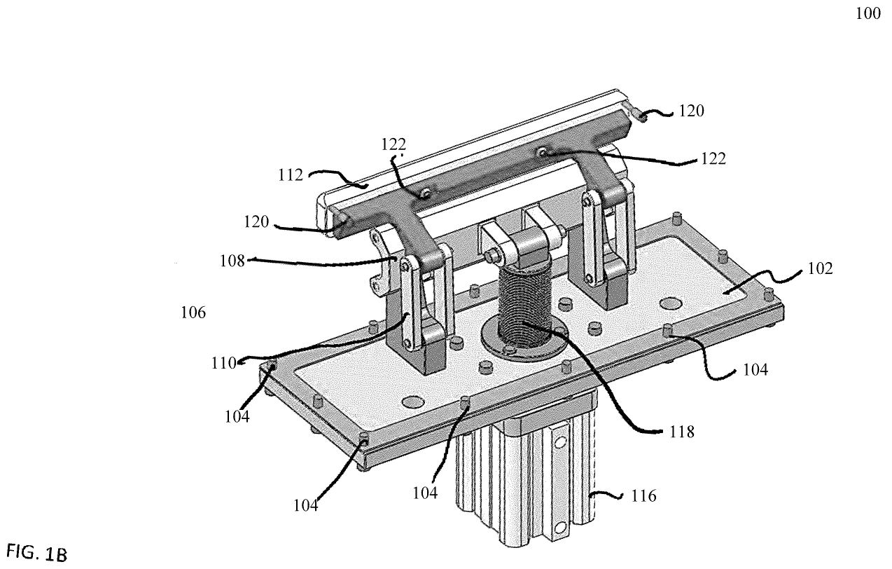

FIGS. 1A and 1B depicts gate valve system 100. Gate valve system 100 includes a mounting plate 102 configured to secure the gate valve system 100 to a wafer handling chamber proximate to a reaction chamber via a number of fasteners 104. When mounting plate 102, fasteners 104 are tightly secured and the position of gate valve system 100 with respect to the reaction chamber is fixed. However, by loosening fasteners 104, the position of gate valve system 100 with respect to the reaction chamber can be adjusted.

Gate valve system 100 includes a hinge mechanism 106 that includes first hinge element 108 (e.g., a first hinge link or rod) and second hinge element 110 (e.g., a second hinge link or rod). First hinge element 108 and second hinge element 110 are coupled to hinge bracket 111 and mounting plate 102. First hinge element 108 and second hinge element 110 are configured as unequal length four bar linkages to enable the specific movements of plate 112 as described herein. Specifically, the four-bar linkage is made up of a fixed link represented by the frame of gate valve system 100, the input link of the four-bar linkage is represented by first hinge element 108, the output link of the four-bar linkage is represented by second hinge element 110 and the coupler or intermediate link (i.e., the element that connects the input link to the output link) is represented by bracket 111 of gate valve system 100. A length of first hinge element 108 (as measured in a straight line between the rotation points at each end of first hinge element 108) is shorter than second hinge element 110 (as measured in a straight line between the rotation points at each end of second hinge element 110).

In various embodiments, to improve or supplement the sealing function of gate valve system 100, hinge mechanism 106 may include various bearings and shafts that are themselves sealed to prevent or reduce contamination of an environment external to the gate valve system 100 and to prevent contamination of the at least one of the bearing and the shaft from gasses exiting the reaction chamber.

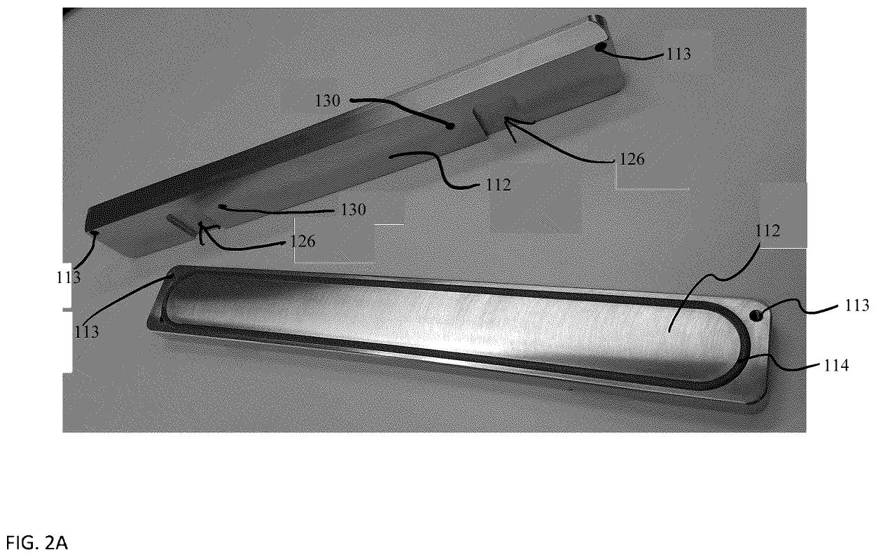

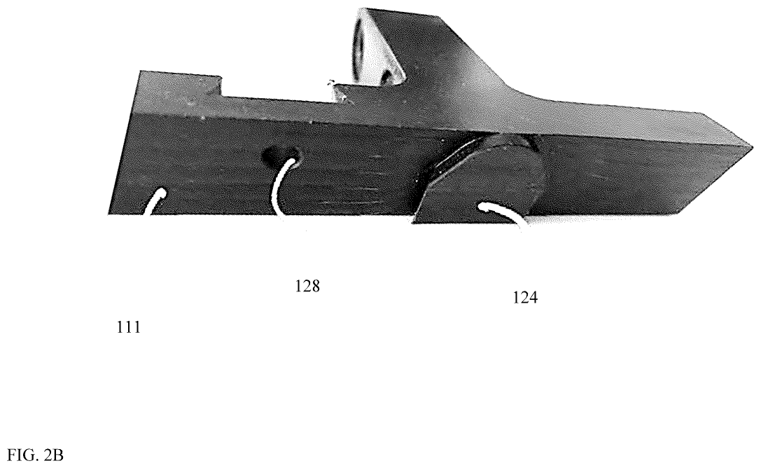

Hinge mechanism 106 is attached to plate 112. The main or front face of plate 112 includes a groove 114 configured to receive a seal element (not shown in FIG. 1A). Typically, the seal element includes a 2-260 Viton 0-ring, though other seal elements and materials may be utilized. FIG. 2A depicts two different plates 112 depicting a groove 114 for receipt of a suitable seal element as well as holes 113 configured to receive distance measuring screws 120 and screws 122 (described below).

In the event that the seal installed in groove 114 of plate 112 requires service or replacement, plate 112 is configured to be removable from bracket 111 to allow servicing of plate 112 away from gate valve system 100 without disconnecting gate valve system 100 from the reactor. Specifically, to remove plate 112 from bracket 111, two screws 122 (see FIG. 1A) are removed and plate 112 is slid off bracket 111. In the depicted embodiment, the connection between plate 112 and bracket 111 takes the form of a dovetail-in-groove joint in which dovetail tenons 124 formed on bracket 111 (see FIG. 2B) are configured to precisely and reliably mate with complementary grooves 126 formed on the back face of plate 112 (see FIG. 2A).

The complementary dovetail tenons 124 and complementary grooves 126 allows plate 112 to be coupled to bracket 111 with precise location control by means of sliding dovetail tenons 124 into complementary grooves 126 such that two screws 122 can be threaded through holes 128 of bracket 111 and fixed to holes 130 of plate 112 (see FIG. 2A) to secure plate 112 to bracket 111.

Gate valve system 100 includes actuator 116 (e.g., an electric motor, servo, or pneumatic drive element) configured to act upon shaft 118 to operate hinge mechanism 106 to move plate 112 between its open and closed positions. In embodiments, actuator 116 may include a flexible metal seal disposed around the shaft 118 of actuator 116, where the flexible metal seal is configured to isolate the internal wafer transfer atmosphere (i.e., the atmosphere internal to the reaction chamber) from an external atmosphere (i.e., the atmosphere external to the reaction chamber and wafer handling chamber).

Gate valve system 100 may include a pair of distance measuring screws 120 that can be threaded through holes 113 in plate 112. During installation of gate valve system 100, gate valve system 100 may be closed so that plate 112 pushes against the reactor housing. Distance measuring screws 120 can then be inserted through holes in plate 112 as a means of measuring the distance between the front face of plate 112 and the reactor housing at the locations in which the distance measuring screws 120 are positioned.

For example, during installation, a technician can attach the mounting plate 102 of gate valve system 100 to the reactor by tightening fasteners 104. The technician can then insert the distance measuring screws 120. By counting the number of turns that must be made to distance measuring screws 120 to cause distance measuring screws 120 to contact the side of the reaction chamber or otherwise precisely measuring the protrusion of distance measuring screws 120 from plate 112, the technician can determine the distance between the plate 112 and the reactor at each distance measuring screw 120 location. If the plate 112 is not squarely positioned against the wall of the reactor or requires other adjustment, the technician can loosen fasteners 104 to allow the technician to adjust the position of the gate valve system 100 with respect to the reactor.

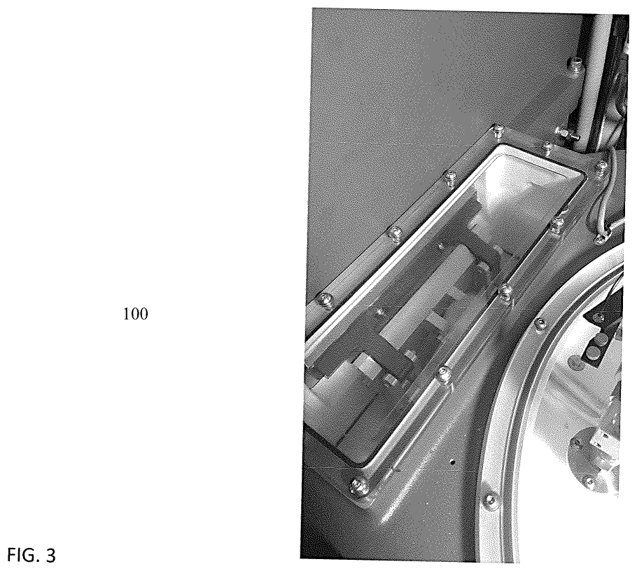

FIG. 3 is a photograph depicting an example installed of gate valve system 100 in conjunction with a reaction chamber.

During operation of gate valve system 100, hinge mechanism 106 is configured so that when gate valve system 100 is opened, plate 112 is pulled down below the opening of the reaction chamber, thereby translating plate 102 below the wafer transfer path, so that the seal installed into groove 114 of plate 112 is out of view and protected from protected from radiation emanating from within the reaction chamber.

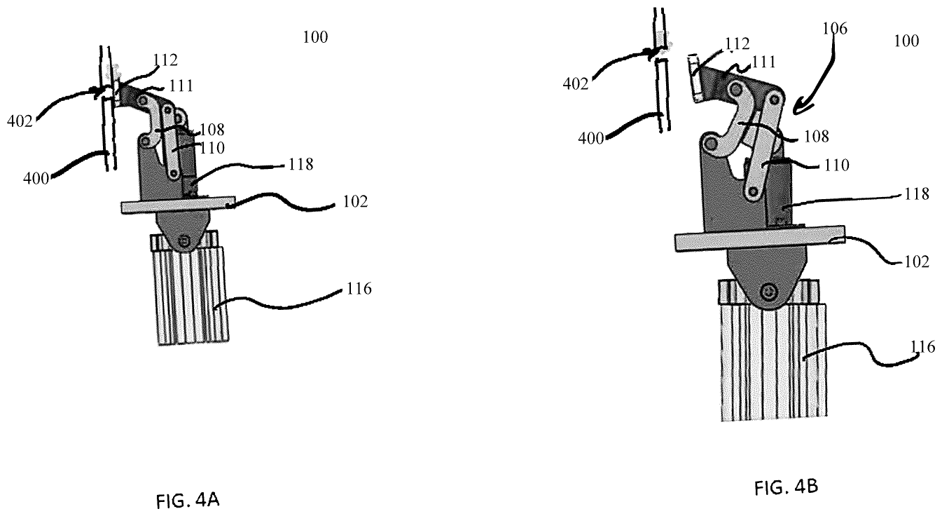

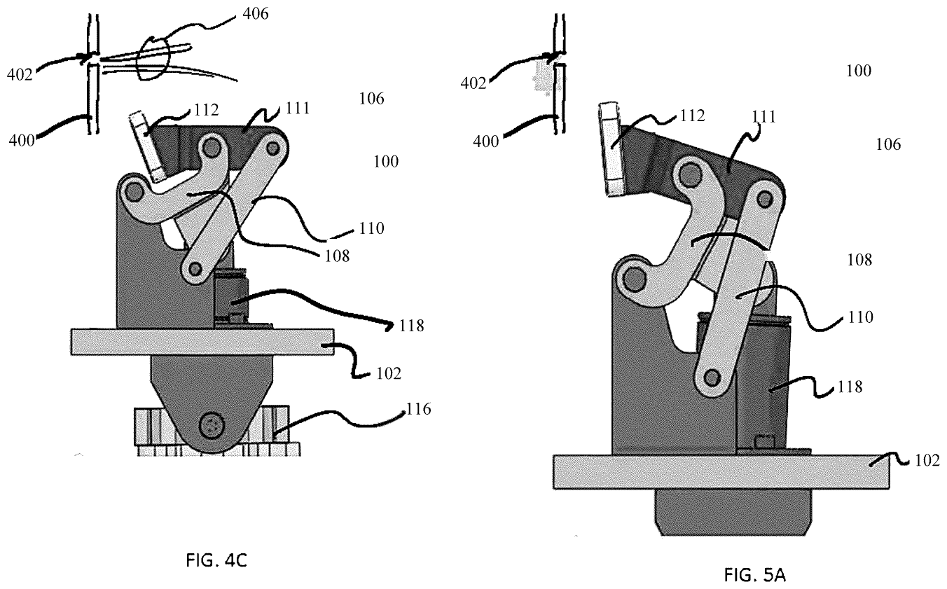

FIGS. 4A-4C depict side views of gate valve system 100 while gate valve system 100 is transitioning from a fully closed position to a fully open position. As shown, in its closed position (FIG. 4A), plate 112 is pushed against the wall 400 of the reaction chamber so as to cover opening 402. To open gate valve system 100, actuator 116 is operated to exert a downwards (as depicted in FIG. 4A) force to pull downwards on shaft 118. This causes hinge mechanism 106 to operate to open gate valve system 100.

FIG. 4B depicts gate valve system 100 midway through the opening process. FIG. 4C depicts gate valve system 100 in its fully open position. As depicted, the operation of hinge mechanism 106 causes plate 112 to be pulled down (as depicted in FIG. 4C) below opening 402. This prevents radiation 406 being emitted through opening 402 and along the wafer transfer path from striking the front surface of plate 112, which could damage the seal disposed within groove 114 of plate 112.

Specifically, during operation because the length of first hinge element 108 is less than first hinge element 108 in the four-bar hinge mechanism, as actuator 116 pulls downwards (as shown in FIGS. 4A-4C) causing second hinge element 110 to rotate to pull plate 112 away from the opening 402 of wall 400, the shorter first hinge element 108 operates to pull plate 112 downwards and out of line-of-sight of the interior of the opening 402 of the wall 400 of the reactor. As discussed, this unequal length four bar linkage arrangement (as represented by hinge mechanism 106) enables not only rotational movement of plate 112 away from the reactor surface but also a downwards (as viewed in FIGS. 4A-4C) translational movement.

During the closing operation of gate valve system 100, the design of hinge mechanism 106 provides that plate 112 is pushed linearly against wall 400 of the reaction chamber. As described herein, this behavior further can prevent damage to the seal of plate 112 by reducing the likelihood of “rolling” of the seal element and potential abrasions to the seal element, which can cause unwanted particles or seal element materials from being dislodged from the seal element such that they may potentially contaminate the reaction chamber, wafers, and environment of the gate valve system 100.

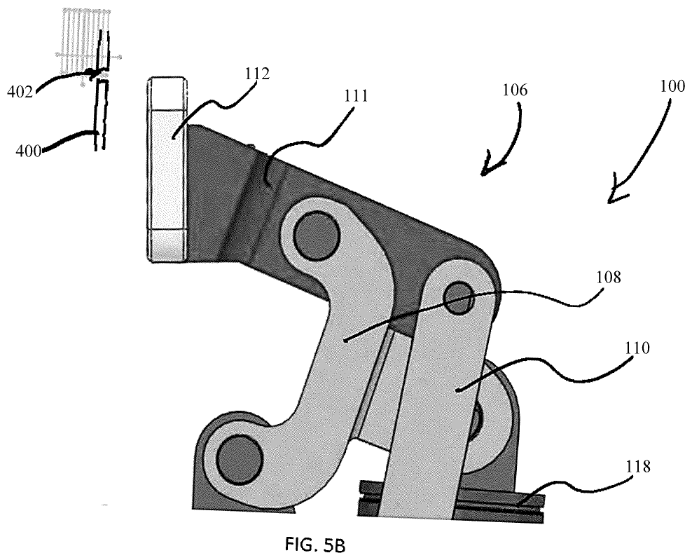

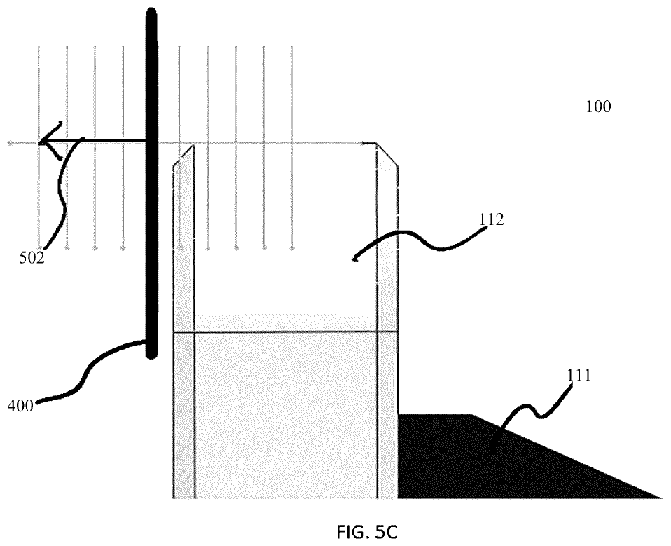

FIGS. 5A-5C depict side views of gate valve system 100 while gate valve system 100 is transitioning from an open position to a closed position. FIGS. 5B and 5C shows “zoomed-in” views to further illustrate the manner in which the plate 112 contacts the outer surface of the reactor wall 400 when gate valve system 100 is closed.

FIG. 5A depicts gate valve system 100 part-way through the closing process. As shown in FIG. 5B and, with more detail, 5C as the closing process completes, plate 112 is parallel to the surface of wall 400 of the rection chamber and thereby engages the surface of wall 400 via parallel and orthogonal engagement between the surfaces of wall 400 and the sealing element of plate 112.

In various embodiments, wall 400 of the reactor may include a flange formed around an opening in the wall 400 of the reaction chamber. At the very end of the closing process (FIG. 5C), plate 112 moves in a direction 502 that is orthogonal to the surface of wall 400 to provide that plate 112 is pressed directly onto 400 and is not slid across the surface of wall 400 (as is found in some conventional gate valve designs). This is in contrast to conventional gate valve designs in which valve plates are pressed against the reaction chamber, which results in sliding of the seal element along the outer surface of the reaction chamber.

Although gate valve system 100 has been described in various embodiments as being used in conjunction with a reaction chamber, it should be understood that gate valve system 100 may be used to operate as a gate valve to securely cover and seal opening formed in various semiconductor fabrication reactors. Furthermore, in various embodiments, gate valve system 100 may be utilized in any semiconductor tooling system in which gate valve system 100 may operate to provide a gate sealing surface that may be benefit from a parallel engagement of the sealing surface.

In some aspects, the techniques described herein relate to a gate valve configured to engage an outer surface of a flange of a wall of a reaction chamber to form a seal about an opening in the wall of the reaction chamber, the gate valve including: a plate including a groove; a seal element disposed within the groove; and a hinge mechanism coupled to the plate and to the reaction chamber, the hinge mechanism being configured to translate between a closed position in which the plate and the seal element are pressed against the wall of the reaction chamber in a direction that is perpendicular to the outer surface of the wall and an open position in which the plate and the seal element are not in direct contact with the reaction chamber.

In some aspects, the techniques described herein relate to a gate valve, wherein when the hinge mechanism is in the open position, the plate is translated away from a wafer transfer path of the reaction chamber.

In some aspects, the techniques described herein relate to a gate valve, wherein when the hinge mechanism is in the open position, the plate is translated below the opening in the wall of the reaction chamber.

In some aspects, the techniques described herein relate to a gate valve, wherein when the hinge mechanism is in the open position the seal element is not in a path of radiation emitted from the opening in the wall of the reaction chamber.

In some aspects, the techniques described herein relate to a gate valve, wherein when the hinge mechanism is in the closed position, the seal element forms the seal with the outer surface of the reaction chamber configured to retain at least one of a toxic and caustic gas within the reaction chamber.

In some aspects, the techniques described herein relate to a gate valve, wherein the gate valve is disposed within a wafer handling chamber and the plate is removable from the hinge mechanism to allow a maintenance operation on the gate valve without disconnecting the hinge mechanism from the reaction chamber or removing the gate valve from the wafer handling chamber.

In some aspects, the techniques described herein relate to a gate valve, wherein the plate is configured to receive at least two distance measuring screws configured to enable measuring of a distance between a surface of the plate and the outer surface of the flange of the reaction chamber when the hinge mechanism is in the closed position to facilitate installation of the gate valve on to the reaction chamber.

In some aspects, the techniques described herein relate to a gate valve, wherein the plate is configured to be coupled to the hinge mechanism at a coupling that does not require realignment of the gate valve when the plate is coupled to the hinge mechanism.

In some aspects, the techniques described herein relate to a gate valve, wherein the hinge mechanism includes a tenon configured to removably engage a complementary groove on the plate to form a dovetail joint between the hinge mechanism and the plate.

In some aspects, the techniques described herein relate to a gate valve, wherein the hinge mechanism includes at least one of a bearing and a shaft and the at least one of the bearing and the shaft is sealed to prevent contamination of an environment of the gate valve and to prevent a contamination of the at least one of the bearing and the shaft from gasses exiting the reaction chamber.

In some aspects, the techniques described herein relate to a gate valve, wherein the hinge includes an unequal length four bar linkage that allows linear motion during contact of the seal element against the flange of the reaction chamber.

In some aspects, the techniques described herein relate to a gate valve, further including an actuator coupled to the hinge mechanisms, the actuator being configured to translate the hinge mechanism between the open position and the closed position and wherein the actuator includes a flexible metal seal disposed around a shaft of the actuator to isolate an internal wafer transfer atmosphere from an external atmosphere.

In some aspects, the techniques described herein relate to a gate valve configured to engage an outer surface of a flange of a wall of a reaction chamber to form a seal about an opening in the wall of the reaction chamber, the gate valve including: a plate including a groove; a seal element disposed within the groove; a bracket removably coupled to the plate; a frame; a first hinge rod connected between the frame and the bracket; a second hinge rod connected between the frame and the bracket, wherein a length of the first hinge rod is less than a length of the second hinge rod; and a hinge mechanism including an unequal four-bar linkage that includes the frame, the first hinge rod, the second hinge rod, and the bracket, wherein the frame is configured to couple to the reaction chamber, the hinge mechanism being configured to translate between a closed position in which the plate and the seal element are pressed against the wall of the reaction chamber in a direction that is perpendicular to the outer surface of the wall and an open position in which the plate and the seal element are not in direct contact with the reaction chamber.

In some aspects, the techniques described herein relate to a gate valve, wherein when the hinge mechanism is in the open position the seal element is not in a path of radiation emitted from the opening in the wall of the reaction chamber.

In some aspects, the techniques described herein relate to a gate valve, wherein the gate valve is configured to be disposed within a wafer handling chamber and the plate is removable from the hinge mechanism to allow a maintenance operation on the gate valve without disconnecting the hinge mechanism from the reaction chamber.

In some aspects, the techniques described herein relate to a gate valve, wherein the plate is configured to receive at least two distance measuring screws configured to enable measuring of a distance between a surface of the plate and the outer surface of the flange of the reaction chamber when the hinge mechanism is in the closed position.

In some aspects, the techniques described herein relate to a gate valve, wherein the plate is configured to be coupled to the bracket by a dovetail connection.

In some aspects, the techniques described herein relate to a gate valve, including: a plate including a groove; a seal element disposed within the groove; a bracket removably coupled to the plate; a frame; a first hinge rod connected between the frame and the bracket; a second hinge rod connected between the frame and the bracket, wherein a length of the first hinge rod is less than a length of the second hinge rod; and a hinge mechanism including an unequal four-bar linkage that includes the frame, the first hinge rod, the second hinge rod, and the bracket, wherein, when the frame is coupled to a flange of a reaction chamber, the hinge mechanism is configured to translate between a closed position in which the plate and the seal element are pressed against the flange of the reaction chamber in a direction that is perpendicular to an outer surface of the flange and an open position in which the plate and the seal element are not in direct contact with the reaction chamber.

In some aspects, the techniques described herein relate to a gate valve, wherein the plate is configured to receive at least two distance measuring screws configured to enable measuring of a distance between a surface of the plate and an outer surface of the flange of the reaction chamber.

In some aspects, the techniques described herein relate to a gate valve, wherein the plate is configured to be coupled to the bracket by a dovetail connection.

Although the invention(s) is/are described herein with reference to specific embodiments, various modifications and changes can be made without departing from the scope of the present invention(s), as set forth in the claims below. Accordingly, the specification and figures are to be regarded in an illustrative rather than a restrictive sense, and all such modifications are intended to be included within the scope of the present invention(s). Any benefits, advantages, or solutions to problems that are described herein with regard to specific embodiments are not intended to be construed as a critical, required, or essential feature or element of any or all the claims.

Unless stated otherwise, terms such as “first” and “second” are used to arbitrarily distinguish between the elements such terms describe. Thus, these terms are not necessarily intended to indicate temporal or other prioritization of such elements. The term “coupled” is defined as connected, although not necessarily directly, and not necessarily mechanically. The terms “a” and “an” are defined as one or more unless stated otherwise. The terms “comprise” and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system, device, or apparatus that “comprises,” “has,” “includes” or “contains” one or more elements possesses those one or more elements but is not limited to possessing only those one or more elements. Similarly, a method or process that “comprises,” “has,” “includes” or “contains” one or more operations possesses those one or more operations but is not limited to possessing only those one or more operations.

What is claimed is:

1. A gate valve configured to engage an outer surface of a flange of a wall of a reaction chamber to form a seal about an opening in the wall of the reaction chamber, the gate valve comprising:
a plate including a groove;
a seal element disposed within the groove; and
a hinge mechanism coupled to the plate and to the reaction chamber, the hinge mechanism being configured to translate between a closed position in which the plate and the seal element are pressed against the wall of the reaction chamber in a direction that is perpendicular to the outer surface of the wall and an open position in which the plate and the seal element are not in direct contact with the reaction chamber.

2. The gate valve of claim 1, wherein when the hinge mechanism is in the open position, the plate is translated away from a wafer transfer path of the reaction chamber.

3. The gate valve of claim 1, wherein when the hinge mechanism is in the open position, the plate is translated below the opening in the wall of the reaction chamber.

4. The gate valve of claim 3, wherein when the hinge mechanism is in the open position the seal element is not in a path of radiation emitted from the opening in the wall of the reaction chamber.

5. The gate valve of claim 1, wherein when the hinge mechanism is in the closed position, the seal element forms the seal with the outer surface of the reaction chamber configured to retain at least one of a toxic and caustic gas within the reaction chamber.

6. The gate valve of claim 1, wherein the gate valve is disposed within a wafer handling chamber and the plate is removable from the hinge mechanism to allow a maintenance operation on the gate valve without disconnecting the hinge mechanism from the reaction chamber or removing the gate valve from the wafer handling chamber.

7. The gate valve of claim 1, wherein the plate is configured to receive at least two distance measuring screws configured to enable measuring of a distance between a surface of the plate and the outer surface of the flange of the reaction chamber when the hinge mechanism is in the closed position to facilitate installation of the gate valve on to the reaction chamber.

8. The gate valve of claim 1, wherein the plate is configured to be coupled to the hinge mechanism at a coupling that does not require realignment of the gate valve when the plate is coupled to the hinge mechanism.

9. The gate valve of claim 8, wherein the hinge mechanism includes a tenon configured to removably engage a complementary groove on the plate to form a dovetail joint between the hinge mechanism and the plate.

10. The gate valve of claim 1, wherein the hinge mechanism includes at least one of a bearing and a shaft and the at least one of the bearing and the shaft is sealed to prevent contamination of an environment of the gate valve and to prevent a contamination of the at least one of the bearing and the shaft from gasses exiting the reaction chamber.

11. The gate valve of claim 1, wherein the hinge includes an unequal length four bar linkage that allows linear motion during contact of the seal element against the flange of the reaction chamber.

12. The gate valve of claim 1, further comprising an actuator coupled to the hinge mechanisms, the actuator being configured to translate the hinge mechanism between the open position and the closed position and wherein the actuator includes a flexible metal seal disposed around a shaft of the actuator to isolate an internal wafer transfer atmosphere from an external atmosphere.

13. A gate valve configured to engage an outer surface of a flange of a wall of a reaction chamber to form a seal about an opening in the wall of the reaction chamber, the gate valve comprising:
a plate including a groove;
a seal element disposed within the groove;
a bracket removably coupled to the plate;
a frame;
a first hinge rod connected between the frame and the bracket;
a second hinge rod connected between the frame and the bracket, wherein a length of the first hinge rod is less than a length of the second hinge rod; and
a hinge mechanism including an unequal four-bar linkage that includes the frame, the first hinge rod, the second hinge rod, and the bracket, wherein the frame is configured to couple to the reaction chamber, the hinge mechanism being configured to translate between a closed position in which the plate and the seal element are pressed against the wall of the reaction chamber in a direction that is perpendicular to the outer surface of the wall and an open position in which the plate and the seal element are not in direct contact with the reaction chamber.

14. The gate valve of claim 13, wherein when the hinge mechanism is in the open position the seal element is not in a path of radiation emitted from the opening in the wall of the reaction chamber.

15. The gate valve of claim 13, wherein the gate valve is configured to be disposed within a wafer handling chamber and the plate is removable from the hinge mechanism to allow a maintenance operation on the gate valve without disconnecting the hinge mechanism from the reaction chamber.

16. The gate valve of claim 13, wherein the plate is configured to receive at least two distance measuring screws configured to enable measuring of a distance between a surface of the plate and the outer surface of the flange of the reaction chamber when the hinge mechanism is in the closed position.

17. The gate valve of claim 13, wherein the plate is configured to be coupled to the bracket by a dovetail connection.

18. A gate valve, comprising:
a plate including a groove;
a seal element disposed within the groove;
a bracket removably coupled to the plate;
a frame;
a first hinge rod connected between the frame and the bracket;
a second hinge rod connected between the frame and the bracket, wherein a length of the first hinge rod is less than a length of the second hinge rod; and
a hinge mechanism including an unequal four-bar linkage that includes the frame, the first hinge rod, the second hinge rod, and the bracket, wherein, when the frame is coupled to a flange of a reaction chamber, the hinge mechanism is configured to translate between a closed position in which the plate and the seal element are pressed against the flange of the reaction chamber in a direction that is perpendicular to an outer surface of the flange and an open position in which the plate and the seal element are not in direct contact with the reaction chamber.

19. The gate valve of claim 18, wherein the plate is configured to receive at least two distance measuring screws configured to enable measuring of a distance between a surface of the plate and an outer surface of the flange of the reaction chamber.

20. The gate valve of claim 18, wherein the plate is configured to be coupled to the bracket by a dovetail connection.
